(19) United States
(12) Patent Application Publication
(10) Pub. No.: US 2007/0281376 A1
(43) Pub. Date: Dec. 6, 2007

(54) Manufacturing method of light emitting device

(75) Inventor: Masahiro Takahashi, Atsugi (JP)

Correspondence Address: COOK, ALEX, MCFARRON, MANZO, CUMMINGS & MEHLER LTD, SUITE 2850, 200 WEST ADAMS STREET, CHICAGO, IL, 60606, US

(73) Assignee: Semiconductor Energy Laboratory Co., Ltd.

(21) Appl. No.: 11/807,732

(22) Filed: May 30, 2007

(30) Foreign Application Priority Data
Jun. 1, 2006 (JP) 2006-154081

(51) Int. Cl. H01L 21/00

(52) U.S. Cl. 438/22

(57) ABSTRACT

An object is, in a display device, to reduce the light quantity which is totally reflected after being transmitted through an electrode, whereby light extraction efficiency is improved. In addition, it is another object of the present invention to provide a manufacturing method of a display device with high performance, high image quality, and high reliability. In a display device including a light emitting element which includes a first electrode, a light emitting layer, and a second electrode, in which light is taken out from the light emitting layer through the second electrode, one or a plurality of bodies are selectively provided in contact with a surface of the second electrode, from which light is taken out. The body is provided so as to have a side surface with respect to an interface with the second electrode, whereby light which enters the body is taken out as much as possible.

### BACKGROUND OF THE INVENTION

1. Field of Invention

The present invention relates to a device which emits light by transmitting light through an electrode. For example, the present invention relates to a light emitting device provided with a light emitting element.

2. Description of the Related Art

A flat panel display such as a liquid crystal panel has been improved and high quality of an image, lower power consumption, and extension in life has been achieved. In practical application of an electroluminescence panel (hereinafter, referred to as an EL panel) which uses an electroluminescence element (hereinafter, referred to as an EL element) in its pixel, it is desired to utilize characteristics of a self light emitting panel and to realize more crisper and brighter display with lower power consumption. In order to achieve this, power efficiency, such as current-luminance characteristics of a material used in an EL element, has been improved. However, there is a limitation on improvement in power efficiency.

In addition, efficiency of extraction of light which is generated in a light emitting layer in an EL element to outside is low. One of causes of such low light extraction efficiency is that when light generated in the light emitting layer reaches an interface between films with different reflective indices, the light is totally reflected and the totally reflected light is attenuated while propagating inside the EL element, or the totally reflected light is emitted from a side surface of the light emitting element, for example, from an end face of a glass substrate.

Patent Document 1 (Japanese Published Patent Application No. 2002-278477) describes an EL element in which the light quantity which is totally reflected is reduced and light extraction efficiency is improved. In Patent Document 1, a low refractive index layer having a refractive index close to that of the air is provided on a surface of a transparent conductive layer, from which light is taken out, whereby the light extraction efficiency is increased.

### SUMMARY OF THE INVENTION

In Patent Document 1, although the light quantity which is totally reflected between the transparent conductive layer and an air layer is reduced, there is a fear that the light quantity which is totally reflected may increase at the interface between the transparent conductive layer and the low refractive index layer. It is an object of the present invention to reduce the light quantity which is totally reflected after being transmitted through an electrode, whereby the light extraction efficiency is improved. In addition, it is another object of the present invention to provide a manufacturing method of a display device with high performance, high image quality, and high reliability.

As an example of a light emitting element included in a light emitting device of the present invention, an inorganic EL element in which an inorganic material is used as a light emitting material, a light emitting diode in which a semiconductor such as a compound semiconductor or the like is used as a light emitting material, and the like are given. A light emitting element is formed by sequentially stacking a first electrode, a light emitting layer, and a second electrode, over a substrate. Light generated in the light emitting layer is extracted through the second electrode. A light emitting device of the present invention may have at least one light emitting element. Alternatively, a light emitting device of the present invention may have at least one light emitting region (a region in which light can be taken out through the second electrode).

The first electrode is an electrode which can reflect light from the light emitting layer. Alternatively, the first electrode may be an electrode which can transmit light from the light emitting layer. The second electrode is an electrode which can transmit light from the light emitting layer.

The light emitting element may have at least one light emitting layer between the first electrode and the second electrode. The light emitting element may have a plurality of light emitting layers between the electrodes. Further, the light emitting element can have an insulating layer either between the light emitting layer and the first electrode or between the light emitting layer and the second electrode, or both.

One or more bodies are selectively provided to in contact with a surface of the second electrode, from which light is taken out. A refractive index of the body is not limited in particular, but it may preferably equal to or more than the refractive index of the light emitting layer.

“Selectively providing a body” refers to provide the body so as to make the second electrode have a region which is not provided with the body in the light emitting region. In other words, the surface of the second electrode has a region which is covered with the body and a region which is not covered with the body. When the body is provided in this manner, the body comes to have a side surface.

Light generated in the light emitting layer enters the second electrode directly or enters the second electrode after being reflected off the first electrode. Part of light which reaches an interface between the second electrode and the body can enter the body without being totally reflected. Note that when the refractive index of the body is equal to or greater than the reflective index of the light emitting layer, all of the light can enter the body without being totally reflected. This can be derived from Snell's law of geometrical optics and totally reflection conditions.

In the present invention, the body having a side surface is provided so that light which enters the body is taken out as much as possible. This is because even light enters the body with an incident angle with which the light is totally reflected off a top surface of the body, the light strikes the side surface of the body after being totally reflected and can be taken out therethrough. In other words, in the present invention, the light quantity totally reflected off the top surface of the second electrode can be decreased by providing the body, and light can be taken out from the body efficiently. Therefore, the light extraction efficiency can be improved.

As the body, a film with high refractive index is favorably used. The body is formed by an ordinarily film forming method and a photolithography patterning technique, in the present invention. In specific, a film of TiO₂, ITO (Indium Tin Oxide), or the like is formed and photolithography-patterned. Such a film can be formed by a sputtering method, a CVD method, a vapor deposition method, or the like.

In the present invention, a protective film may be provided on a surface of the second electrode, and at least one body can be selectively provided thereover As the protective film, silicon oxide (SiO_{y}, wherein 0<y≦2), silicon nitride (SiNₓ, wherein 0<x≦4/3), silicon nitride oxide (SiNₓO_{y}, wherein 0<x<4/3, 0<y<2, and 0<3x+2y≦4), or the like can be used.

One mode of a manufacturing method of a light emitting device of the present invention includes, forming a first electrode over a substrate, forming a light emitting layer containing an inorganic compound over the first electrode, forming a light transmitting second electrode over the light emitting layer, forming a light transmitting film over the second electrode, forming a mask layer over the light transmitting film, and forming a body selectively on a surface of the second electrode by etching the light transmitting film using the mask layer. Light emitted from the light emitting layer transmits the second electrode and the body.

One mode of a manufacturing method of a light emitting device of the present invention includes, forming a first electrode over a substrate, forming a light emitting layer containing an inorganic compound over the first electrode, forming a light transmitting second electrode over the light emitting layer, forming a photosensitive and light transmitting film over the light transmitting second electrode, and forming a body selectively on a surface of the second electrode by light exposure and development of the photosensitive and light transmitting film. Light emitted from the light emitting layer transmits the second electrode and the body.

One mode of a manufacturing method of a light emitting device of the present invention includes, forming a first electrode over a substrate, forming a light emitting layer containing an inorganic compound over the first electrode, forming a light transmitting second electrode over the light emitting layer, forming a protective layer over the light transmitting second electrode, forming a light transmitting film over the protective layer, forming a mask layer over the light transmitting film, and forming a body selectively on a surface of the light transmitting second electrode with the protective layer between the body and the surface by etching the light transmitting film using the mask layer. Light emitted from the light emitting layer transmits the second electrode and the body.

One mode of a manufacturing method of a light emitting device of the present invention includes, forming a first electrode over a substrate, forming a light emitting layer containing an inorganic compound over the first electrode, forming a light transmitting second electrode over the light emitting layer, forming a protective layer over the light transmitting second electrode, forming a photosensitive and light transmitting film over the protective layer, and forming a body selectively on a surface of the light transmitting second electrode with the protective layer between the body and the surface by light exposure and development of the photosensitive and light transmitting film. Light emitted from the light emitting layer transmits the light transmitting second electrode and the body.

When at least one body is selectively provided over the second electrode, extraction efficiency of light through the second electrode is improved. When the light extraction efficiency is improved, a display device can consume less power. In addition, a method for easily forming a structure which is appropriate for manufacturing such a display device can be provided.

### BRIEF DESCRIPTION OF DRAWINGS

FIGS. 1A to 1C show a structure of a light emitting device (Embodiment Mode 1);

FIGS. 2A to 2C show a structure of a light emitting device (Embodiment Mode 1);

FIG. 3 shows a structure of a light emitting device (Embodiment Mode 1);

FIGS. 4A and 4B each show a structure of a light emitting device (Embodiment Mode 1);

FIGS. 5A to 5C each show a light emitting element which can be applied to the present invention (Embodiment Mode 4);

FIGS. 6A to 6C each show a light emitting element which can be applied to the present invention (Embodiment Mode 4);

FIGS. 7A and 7B show a light emitting device (Embodiment Mode 2);

FIGS. 8A to 8C show a structure of a light emitting device (Embodiment Mode 3);

FIGS. 9A to 9D show electronic appliances to which a light emitting device formed using the present invention is applied (Embodiment Mode 5);

FIG. 10 shows a liquid crystal display device to which a light emitting device formed using the present invention is applied (Embodiment Mode 5);

FIGS. 11A to 11C show a manufacturing method of a light emitting device (Embodiment Mode 1); and

FIGS. 12A to 12D show a manufacturing method of a light emitting device (Embodiment Mode 1).

### DETAILED DESCRIPTION OF THE INVENTION

Hereinafter, embodiment modes in the present invention are described with reference to the accompanying drawings. However, the present invention can be carried out with many different modes. Also, modes can be modified in various ways without departing from the purpose and the scope of the present invention. Accordingly, the present invention should not be interpreted as being limited to the description of the embodiment modes. In addition, the embodiment modes can be appropriately combined without departing from the purpose of the present invention.

### Embodiment Mode 1

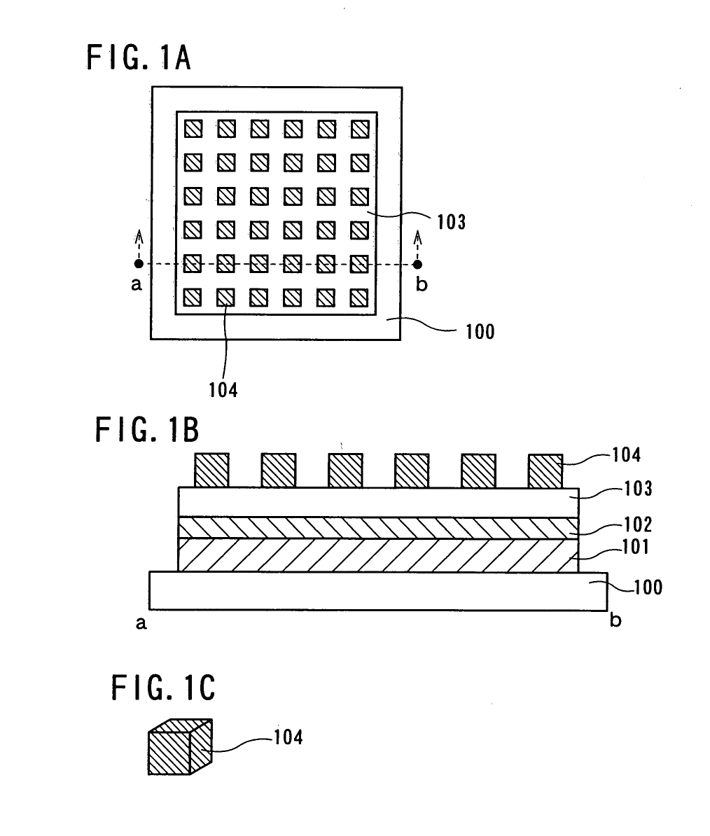

This embodiment mode is described with reference to FIGS. 1A to 6C.

FIGS. 1A to 1C show a light emitting device of this embodiment mode. FIG. 1A is a top view, FIG. 1B is a cross-sectional view taken along a line a-b in FIG. 1A, and FIG. 1C is an external view of a body.

A light emitting element is provided over a substrate 100. In the light emitting element, a first electrode 101, a light emitting layer 102, a second electrode 103 are sequentially stacked over the substrate 100. A plurality of bodies 104 are selectively provided in contact with a surface of the second electrode 103.

The substrate 100 serves as a support body of the light emitting element. For example, a quartz substrate, a semiconductor substrate, a glass substrate, a plastic substrate, a flexible plastic film, or the like can be used as the substrate 100. The substrate 100 is not necessarily transparent and may be colored or opaque because light is not taken out from the substrate 100 side.

The first electrode 101 reflects light generated in the light emitting layer 102. The first electrode 101 is formed of a reflective conductive film which is formed of a metal or an alloy. As examples of the metal film and the alloy film, a film of gold (Au), platinum (Pt), nickel (Ni), tungsten (W), chromium (Cr), molybdenum (Mo), iron (Fe), cobalt (Co), copper (Cu), palladium (Pd), aluminum (Al), or an alloy film containing plural of the foregoing metals, or the like can be given. These films forming the first electrode 101 can be formed by a sputtering method, a vapor deposition method, or the like.

The light emitting layer 102 is formed over the first electrode 101 by a vapor deposition method or the like. The light emitting layer 102 is a layer containing a light emitting substance. The light emitting layer 102 can be formed by, for example, a sputtering method, a vapor deposition method, or the like.

The second electrode 103 is formed over the light emitting layer 102. The second electrode 103 is an electrode which can transmit light generated in the light emitting layer 102. The light generated in the light emitting layer 102 is taken out through the second electrode 103 directly or after being reflected off the first electrode 101.

The second electrode 103 is typically formed of a transparent conductive film. The second electrode 103 can be formed by, for example, a sputtering method, a vapor deposition method, or the like.

Note that the first electrode 101 can be formed as a transparent electrode, which can transmit light, as well as the second electrode 103.

Metal oxide is typically used as a material of a light transmitting conductive film which is used for the first electrode 101 and the second electrode 103. For example, an oxide of one selected from zinc (Zn), indium (In), or tin (Sn), or a compound in which a dopant is added to such an oxide are given. As a dopant of zinc oxide, Al, Ga, B, In, Si, and the like are given, for example. Zinc oxides containing such dopant are referred to as AZO, GZO, BZO, and IZO, respectively. In addition, as a dopant of indium oxide, Sn, Ti, or the like are given. Indium oxide to which Sn is added is referred to as ITO (Indium Tin Oxide), for example. As a dopant of tin oxide, Sb, F; and the like are given. Further, a compound in which two different oxide selected from foregoing zinc oxide, indium oxide, tin oxide, or such an oxide containing a dopant, are contained can be used as the transparent conductive film.

A light emitting element of the present invention is not limited to the structure shown in FIGS. 1A to 1C. The light emitting element may have any structure as long as a light emitting layer is provided between two electrodes. Light emitting elements which utilize electroluminescence are classified according to whether their light emitting materials are an organic compound or an inorganic compound. In general, a light emitting element whose light emitting material is an organic compound are referred to as an organic EL element, while a light emitting element whose light emitting material is an inorganic compound are referred to as an inorganic EL elements.

An inorganic EL element is classified as a dispersion type inorganic EL element or a thin-film type inorganic EL element, depending on its structure. Although these differ in that the former has a light emitting layer in which particles of a light emitting material are dispersed in a binder, whereas the latter has a light emitting layer formed of a thin film of a light emitting material, both of them need electrons accelerated by a high electric field. Note that mechanisms for obtaining light emission are donor acceptor recombination light emission, which utilizes a donor level and an acceptor level, and localized light emission, which utilizes inner-shell electron transition of a metal ion. In general, in many cases, a dispersion type inorganic EL element exhibits donor-acceptor recombination light emission and a thin-film type inorganic EL element exhibits localized light emission.

A plurality of bodies 104 are selectively provided in contact with the surface of the second electrode. The body 104 has a three-dimensional shape of a columnar having a rectangular base. A material for the body 104 is selected from materials which have high light transmissivity against light generated in the light emitting layer. Further, the refractive index of the body 104 is preferably equal to or greater than that of the light emitting layer 102. When the refractive index is thus adjusted, light which strikes an interface between the second electrode 103 and the body 104 is not totally reflected off the interface and can enter the body 104; whereby light extraction efficiency can be further improved.

Since the body 104 has a side surface, even light enters the body 104 with an incident angle with which the light is totally reflected off a top surface of the body 104, the light can be taken out through the side surface of the body 104. Accordingly, the light quantity which can be taken out through the second electrode 103 can be increased.

The body 104 can have a height in the range from 50 nm to 100 μm. The body 104 may have one side of the base equal to or more than 50 nm. Further, the upper limit of the length of one side may be set so that the body 104 can be selectively provided with respect to the second electrode 103, for example, the upper limit can be set as 100 μm.

A shape of the base of the body 104 is not limited to a rectangular shape and may be a polygonal shape such as a triangular, rectangular, or pentagonal shape.

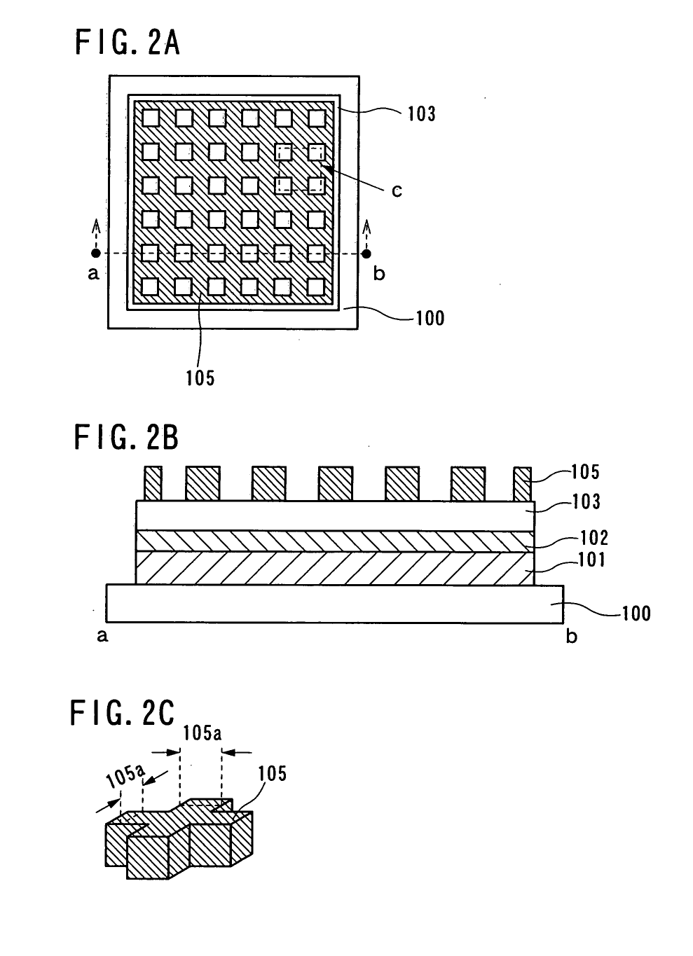

A plurality of bodies 104 are provided in FIGS. 1A to 1C; alternatively, one body 105 can be selectively provided over the second electrode 103 as shown in FIGS. 2A to 2C. FIG. 2A is a top view, FIG. 2B is a cross-sectional view taken along a line a-b in FIG. 2A, and FIG. 2C is an external view of a body cut in a rectangular shape as indicated by a region C in FIG. 2A.

The body 105 has a three-dimensional shape of a rectangular solid provided with a plurality of openings. The body 104 and the body 105 relate each other in the following manner: in a region in which the body 105 is provided, the body 104 in FIGS. 1A to 1C is not provided, whereas in a region in which the body 105 is not provided, the body 104 in FIGS. 1A to 1C is provided. The opening of the body 105 has a columnar shape as the body 104 has. The shape of the opening in the body 105 (a shape of a base of the opening) is not limited to a rectangular shape, and may be a polygonal shape such as a triangular, rectangular, or pentagonal shape.

The body 105 can have a height in the range from 50 nm to 100 μm. A width 105a may be equal to or longer than 50 nm. Further, the upper limit of the width 105a may be set so that the body 105 can be selectively provided with respect to the second electrode 103; for example, the upper limit can be set as 100 μm.

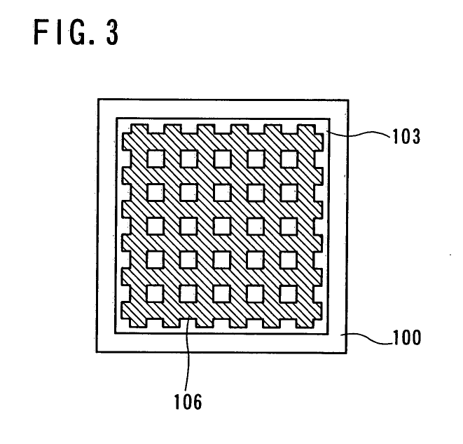

Further, as shown in FIG. 3, a body 106 in which prisms are assembled to form a shape of parallel crosses can be provided. The size of the body 106 can be determined similarly to the body 105.

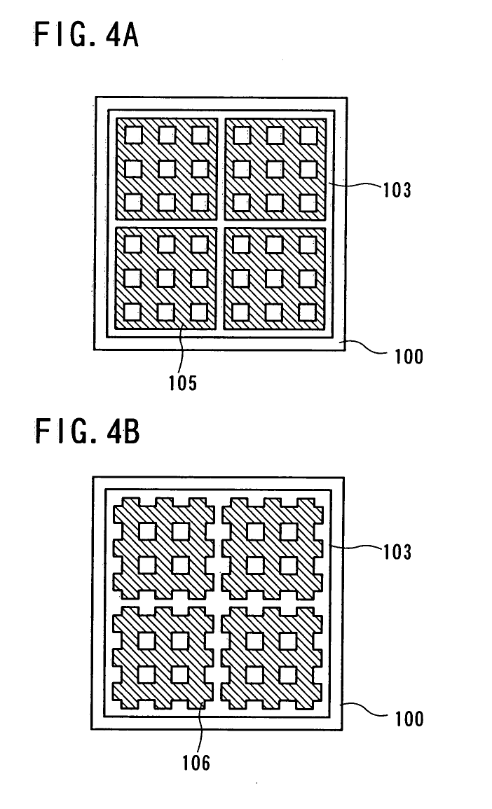

In addition, as shown in FIGS. 4A and 4B, the plurality of bodies 105 or the plurality of bodies 106 can be provided over one second electrode 103.

A protective film can be provided on the surface of the second electrode 103 and the body can be formed on a surface of the protective film. As the protective film, a film of silicon oxide (SiO_{y}, wherein 0<y≦2), silicon nitride (SiNₓ, wherein 0<x≦4/3), silicon nitride oxide (SiNₓO_{y}, wherein 0<x<4/3, 0<y<2, and 0<3x+2y≦4), or the like can be used. A thickness of the protective film may be 0.1 μm or more, and may be in the range of 0.1 to 10 μm.

As will be described later in Embodiment Mode 2, a sealing substrate is secured to an element substrate which is provided with the element, so that the light emitting element is sealed. Space between the substrates is filled with a sealing member formed of a gas or a resin. As the resin for the sealing, a resin with a refractive index close to that of the air is preferable. In addition, in a case of filling with a resin, a resin in a liquid phase state is used for filling the space and hardened. When the resin is hardened, there is a fear that force is applied to a film forming the light emitting element, and the characteristics of the light emitting element are affected. If a thickness of the protective film is 1 μm or more, such an effect can be eliminated, which is preferable.

In this embodiment mode, a case in which a light emitting element is sealed by a glass substrate is shown. Sealing is a treatment for protecting the light emitting element from moisture, and is performed employing any of the following methods: a method in which the light emitting element is mechanically sealed with a cover material, a method in which the light emitting element is sealed with a thermosetting resin or an ultraviolet curing resin, and a method in which the light emitting element is sealed with a thin film having a high barrier property, such as a film of metal oxide or metal nitride. The cover material can be glass, ceramic, plastic, plastic, or metal. Alternatively, a flexible substrate may be used as the cover material. A flexible substrate is a bendable (flexible) substrate, for example, a plastic substrate formed of polycarbonate, polyarylate, polyethersulfone, or the like. Alternatively, a film (which is formed from polypropylene, polyester, vinyl, poly vinyl fluoride, vinyl chloride, or the like), a base film (which is formed from polyester, polyamide, an inorganic evaporated film, or the like), and the like can be used. When light is emitted through the cover material, the cover material needs to be light transmitting.

In the present invention, the body can be formed using a photolithography patterning technique. A photolithography patterning technique, which is a method for forming a pattern, is a technique to transfer a pattern of a circuit or the like, which is formed over a transparent flat plane using a material which does not transmit light and is referred to as a photomask, to a targeted substrate by utilizing light.

In a manufacturing process using a photolithography patterning technique, the body, which is a pattern, is formed using a mask pattern formed of a photosensitive organic resin material referred to as photoresist, through steps of light exposition, development, baking, separation, and the like. Therefore, in etching of a film in a manufacturing process, a treatment with use of a chemical solution typified by an etchant or the like, that is, a so-called wet process is used.

A light emitting element used in the present invention is an inorganic EL element in which an inorganic electroluminescent material is used. Therefore, the light emitting element is hardly damaged when a photolithography patterning technique including a wet process is used in formation of the body over the second electrode layer of the light emitting element. Thus, the body for improving light extraction efficiency of light emitted from the light emitting element can be manufactured in an upper part of the light emitting element without damaging the characteristics of the light emitting element.

In addition, in a photolithography patterning technique, a light transmitting film is formed and a mask layer which is formed of a resist and various etching methods (dry etching and wet etching) are combined, which allows wider choice of materials which can be processed for a light transmitting film. Therefore, a material with optimum optical characteristics for improving light extraction efficiency can be freely determined regardless of a processing method. Accordingly, light emitted from the light emitting element can be efficiently taken out of the light emitting device including the light emitting element because of the body provided in an upper part of the light emitting element.

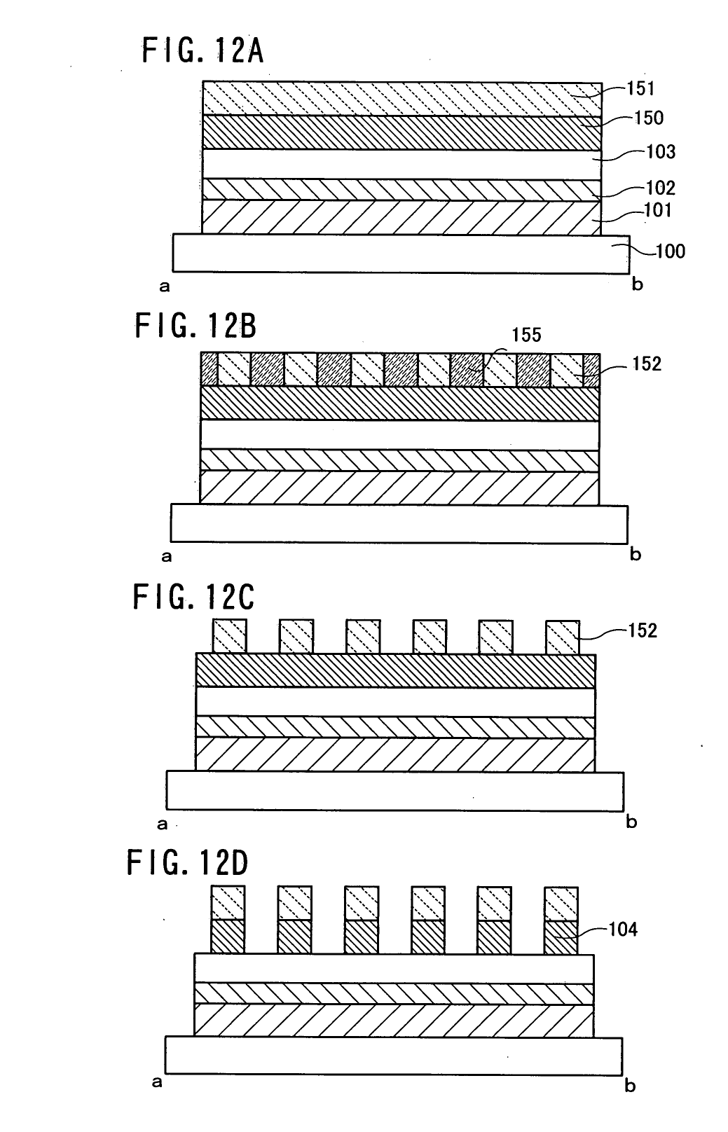

In the present invention, the body provided in an upper part of the light emitting element can be formed in this manner: a light transmitting film is formed, and is processed into the body having a desired shape using a mask layer which is formed by light exposition and development. As shown in FIGS. 12A to 12D, a light transmitting film 150 and a mask layer 151 are formed over a first substrate 100, a first electrode 101, a light emitting layer 102, and a second electrode 103 (see FIG. 12A). The mask layer 151 is selectively exposed to light and a light-exposed region 155 is formed (see FIG. 12B). When the mask layer is a positive type, the light-exposed region is removed by etching. When the mask layer is a negative type, a non-light-exposed region is removed by etching. A mask layer 152 is formed by a developing treatment (see FIG. 12C). The light transmitting film 150 is etched and processed using the mask layer 152, whereby the body 104 is formed (see FIG. 12D).

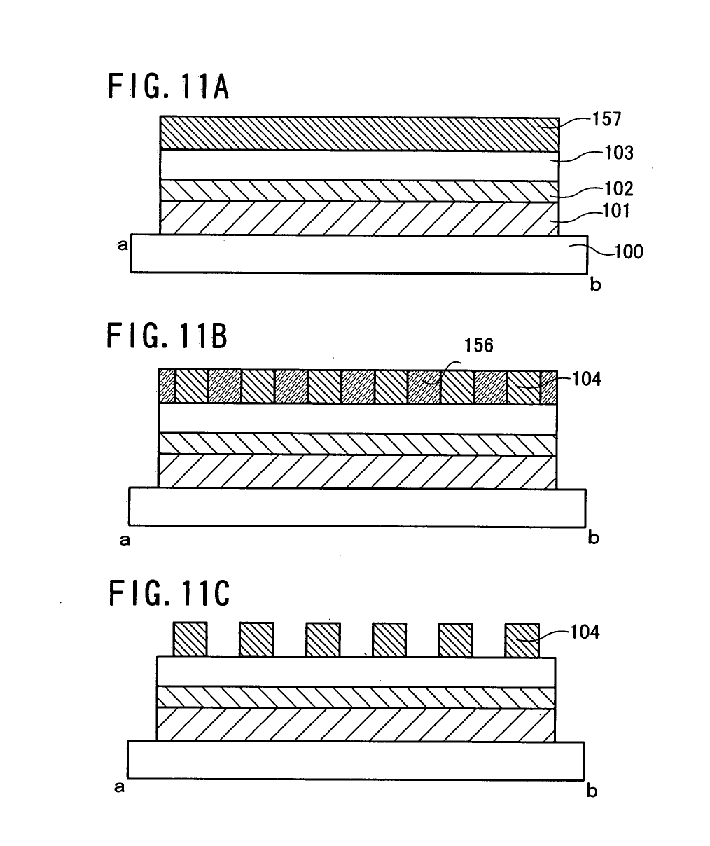

Alternatively, the body can be formed of a photosensitive light transmitting film, such as a film of a photosensitive resin material, by light exposure and development, without using a mask layer. As shown in FIGS. 11A to 11C, a photosensitive light transmitting film 157 is formed over the first substrate 100, the first electrode 101, the light emitting layer 102, and the second electrode 103 (see FIG. 11A). The photosensitive light transmitting film 157 is selectively exposed to light and a light-exposed region 156 is formed (see FIG. 11B). When the photosensitive light transmitting film is a positive type, the light-exposed region is removed by etching. When the photosensitive light transmitting film is a negative type, a non-light-exposed region is removed by etching. The photosensitive light transmitting film is etched and processed by a developing treatment, whereby the body 104 is formed (see FIG. 11C).

As a forming method of the light transmitting film, various methods can be used. In specific, the light transmitting film can be formed by a vacuum evaporation method such as a resistive heating evaporation method or an electron beam evaporation (EB evaporation) method, a physical vapor deposition (PVD) method such as a sputtering method, a chemical vapor deposition (CVD) method such as a metal organic CVD method or a low-pressure hydride transport CVD method, an atomic layer epitaxy (ALE) method, or the like. Alternatively, an ink jet method, a spin coating method, or the like can be used. A light transmitting film of polyimide, acrylic, silicon oxide, silicon titanium, or the like is used.

In the present invention, the mask layer may be formed by a method with which a pattern can be selectively formed, such as a droplet discharging method. In a droplet discharging (ejecting) method (also referred to as an ink jet method in accordance with its system), a droplet of a composition prepared for a specific purpose is selectively discharged (ejected), so that a predetermined pattern (such as a conductive layer or an insulating layer) can be formed. A treatment for controlling wettability or adhesion of a region where a pattern is to be formed may be performed at this time as well. Alternatively, a method for transferring or drawing a pattern, such as a printing method (a method with which a pattern is formed, e.g., screen printing or offset printing), a dispenser method, or the like can be used.

As the mask layer which is used in this embodiment mode, a resin material such as an epoxy resin, an acrylic resin, a phenol resin, a novolac resin, a melamine resin, or a urethane resin. Alternatively, an organic material such as benzocyclobutene, parylene, fluorinated arylene ether, or polyimide which transmits light, a compound material formed by polymerization of siloxane-based polymer, or the like, a composition material containing a water-soluble homopolymer and a water-soluble copolymer, or the like can be used. Further alternatively, a commercial resist material containing a photosensitizer may be used, for example, a positive resist or a negative resist may be used. In a case of using a droplet discharging method, surface tension and viscosity of any material which is used can be controlled by adjusting a concentration of a solvent by adding a surfactant or the like to the solvent.

The etching process for forming a desired shape may be performed by either plasma etching (dry etching) or wet etching. As an etching gas, fluorine-based gas such as CF₄ or NF₃ or a chlorine-based gas such as Cl₂ or BCl₃ may be used, and an inert gas such as He or Ar may be mixed into the etching gas as appropriate.

In this embodiment mode, when at least one body is selectively provided over the second electrode, extraction efficiency of light through the second electrode is improved. When the light extraction efficiency is improved, a display device consumes less power. In addition, a structure which is appropriate for manufacturing such a display device can be easily provided.

### Embodiment Mode 2

In this embodiment mode, an active matrix light emitting device in which operation of a light emitting element is controlled by a transistor is described.

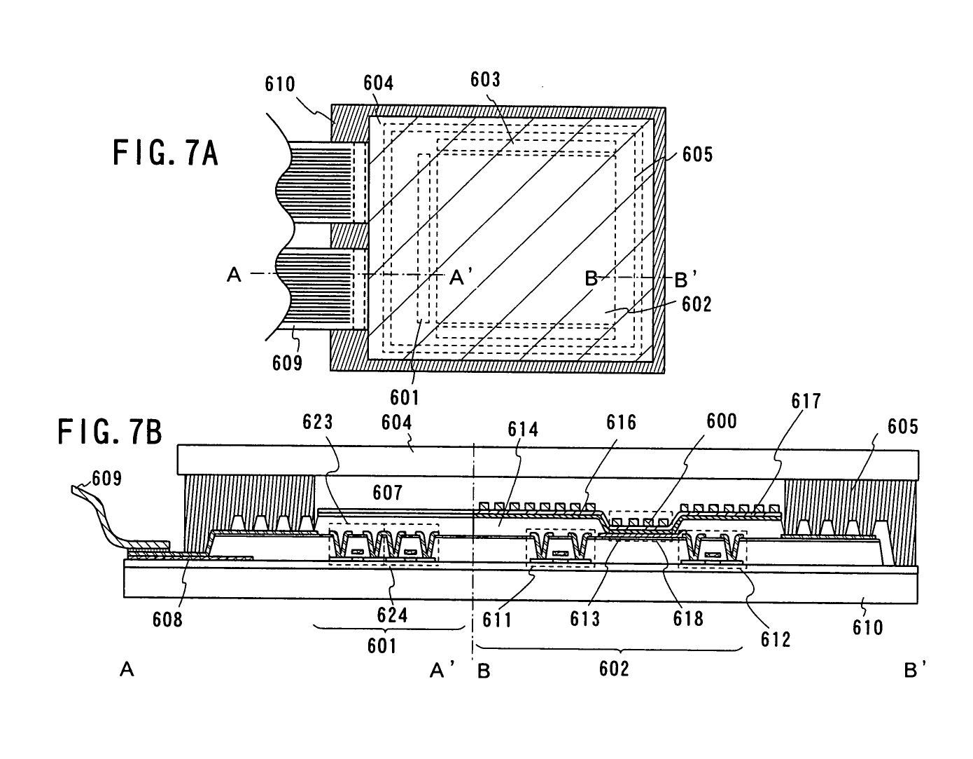

In this embodiment mode, a light emitting device including a pixel portion including a light emitting element to which the present invention is applied is described with reference to FIGS. 7A and 7B. FIG. 7A is a top view showing a light emitting device, FIG. 7B is a cross-sectional view taken along lines A-A′ and B-B′ in FIG. 7A. Reference numeral 601 denotes a driver circuit portion (source side driver circuit), 602 denotes a pixel portion, and 603 denotes a driver circuit portion (gate side driver circuit), each of which is shown by a dotted line. Reference numeral 604 denotes a sealing substrate, 605 denotes a sealing member, and 607 denotes space surrounded by the sealing member 605.

A lead wiring 608 transmits a signal to be inputted to the source side driver circuit 601 and the gate side driver circuit 603 and receives a video signal, a clock signal, a start signal, a reset signal, or the like from an FPC (Flexible Printed Circuit) 609 which is an external input terminal. Note that although only an FPC is illustrated here, a printed wiring board (PWB) may be attached thereto. The light emitting device in this specification includes not only a light emitting device itself but also a light emitting device provided with an FPC or a PWB.

Then, a cross-sectional structure is described with reference to FIG. 7B. The drive circuit portion and the pixel portion are formed over an element substrate 610. Here, the source side driver circuit 601, which is a driver circuit portion and a pixel in the pixel portion 602 are illustrated.

Note that as the source side driver circuit 601, a CMOS circuit in which an n-channel TFT 623 and a p-channel TFT 624 are combined is formed. The driver circuit may be formed with use of a known CMOS circuit, a PMOS circuit, or an NMOS circuit. Although a driver integration type in which a driver circuit is formed over the substrate is described in this embodiment mode, it is not always necessary. The driver circuit is not necessarily formed over the substrate, but outside the substrate. Further, a structure of the TFT is not particularly limited. Either a staggered TFT or an inversely staggered TFT may be employed. Also, the crystallinity of a semiconductor film used in the TFT is not particularly limited. Either an amorphous semiconductor film or a crystalline semiconductor film may be used. In addition, a semiconductor material is not limited and an inorganic compound or an organic compound may be used.

The pixel portion 602 includes a plurality of pixels each having a switching TFT 611, a current control TFT 612, and a first electrode 613 electrically connected to a drain region of the current control TFT 612. Note that an insulator 614 is formed to cover an end portion of the first electrode 613. Here, the insulator 614 is formed with use of a positive photosensitive acrylic resin film.

The insulator 614 is formed to have a curved surface with curvature at an upper end or a lower end so as to be covered favorably. For example, in a case where positive photosensitive acrylic is used as a material of the insulator 614, the insulator 614 is preferably formed to have a curved surface with a curvature radius (0.2 to 3 μm) only at an upper end. Either a negative type photosensitive material which becomes insoluble in an etchant by light irradiation or a positive type photosensitive material which becomes soluble in an etchant by light irradiation can be used as the insulator 614.

A light emitting layer 616 and a second electrode 617 are formed over the first electrode 613. At least the second electrode 617 among the first electrode 613 and the second electrode 617 transmits light so that light emitted from the light emitting layer 616 can be taken out.

A body 600 described in Embodiment Mode 1 is provided over the second electrode 617. Although the body 600 is provided over the entire surface of the second electrode 617 in FIGS. 7A and 7B, the body 600 may be formed over the second electrode 617 only in a light emitting region (a region included in a light emitting element 618).

Various methods can be used as a forming method of the first electrode 613, the light emitting layer 616, and the second electrode 617. In specific, a vacuum vapor deposition method such as a resistance heating vapor deposition method or an electron beam vapor deposition (EB vapor deposition) method, a physical vapor deposition (PVD) method such as a sputtering method, a chemical vapor deposition (CVD) method such as an organic metal CVD method or a hydride transport reduced pressure CVD method, an atomic layer epitaxy (ALE) method, or the like can be used. Alternatively, an ink jet method, a spin coating method, or the like can be used. In addition, a film forming method may differ between the electrodes and the layers. Note that the light emitting layer included in the light emitting layer 616 may be preferably formed by a film forming apparatus and a film forming method described in Embodiment Mode 1.

The sealing substrate 604 and the element substrate 610 are attached to each other with the sealing member 605. Accordingly, a structure in which the light emitting element 618 is provided in the space 607 surrounded by the element substrate 610, the sealing substrate 604, and the sealing member 605 is formed. Note that the space 607 is filled with a filler. The filler may be a sealing member formed of a resin, as well as an inert gas (such as nitrogen or argon).

Note that an epoxy-based resin is preferably used as the sealing member 605. A material of the sealing member 605 desirably allows as little moisture and oxygen as possible to be transmitted. As the sealing substrate 604, a plastic substrate formed of FRP (Fiberglass-Reinforced Plastics), PVF (polyvinyl fluoride), polyester, acrylic, or the like can be used, as well as a glass substrate and a quartz substrate.

As described above, when at least one body is selectively provided over the second electrode, the extraction efficiency of light through the second electrode is improved in an active matrix light emitting device. When the light extraction efficiency is improved, power consumption of a display device can be reduced. In addition, a structure which is appropriate for manufacturing such a display device can be easily formed.

### Embodiment Mode 3

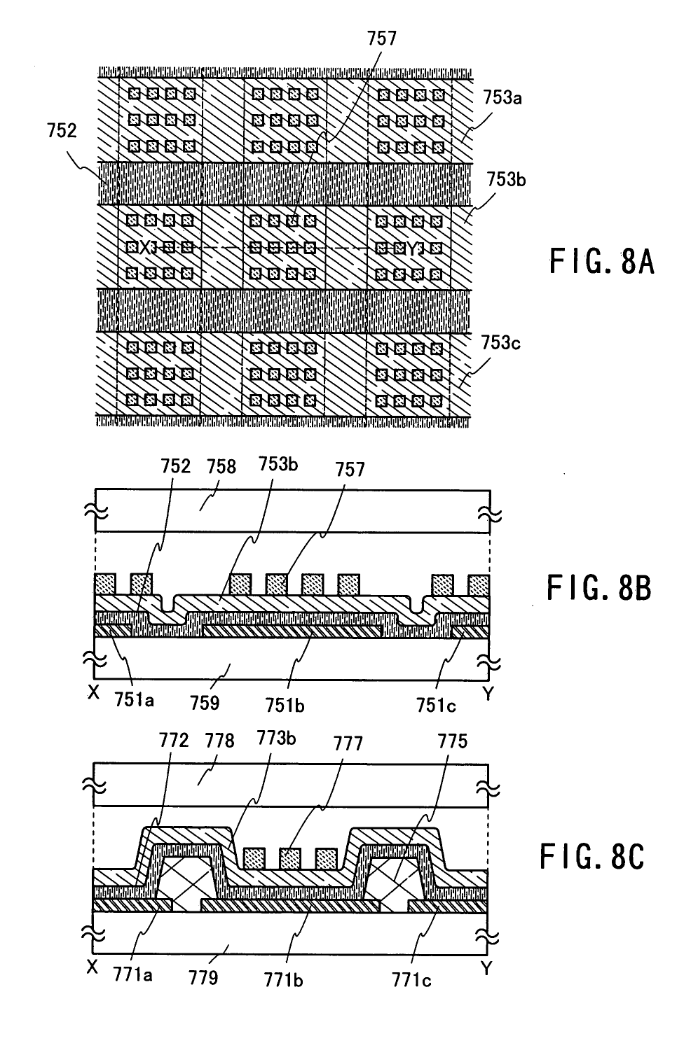

FIGS. 8A to 8C show perspective views of a passive matrix light emitting device manufactured according to the present invention.

In FIGS. 8A to 8C, FIG. 8A shows a top view of a passive matrix light emitting device to which the present invention is applied and FIGS. 8B and 8C are cross-sectional views taken along a line X-Y in FIG. 8A.

The display device includes a substrate 759, a first electrode layer 751a, a first electrode layer 751b, and a first electrode layer 751c which are extended in a first direction, an electroluminescent layer 752 which is formed so as to cover the first electrode layer 751a, the first electrode layer 751b, and the first electrode layer 751c, and a second electrode layer 753a, a second electrode 753b, and a second electrode layer 753c which are extended in a second direction perpendicular to the first direction, and a substrate 758 (see FIGS. 8A and 8B). The electroluminescent layer 752 is provided between the first electrode layers 751a to 751c and the second electrode layers 753a to 753c. Note that in a case in which influence of an electric field in a lateral direction between adjacent cells is concerned, the electroluminescent layer 752 provided for the light emitting elements may be separated. The second electrode layers 753a to 753c are light transmitting electrodes. The first electrode layers 751a to 751c may be either reflective electrodes or light transmitting electrodes. A rectangular solid body 757 is provided over the second electrode layers 753a to 753c in an upper part of a light emitting element, thus light extraction efficiency is improved. Needless to say, the body 757 may have another shape.

The first electrode layers 751a to 751c may have tapered shapes or may have shapes in which a curvature radius changes continuously. When the first electrode layers 751a to 751c have shapes having curved surfaces with curvature, favorable coverage of an insulating layer and a conductive layer to be stacked can be obtained.

Further, a partition (insulating layer) may be formed so as to cover end portions of the first electrode layers 751a to 751c. The partition (insulating layer) serves as a wall separating one memory element from another. FIG. 8C illustrates a structure where end portions of the first electrode layers are covered with the partition (insulating layer).

An example of a light emitting element shown in FIG. 8C has a structure in which a substrate 779 and a partition (insulating layer) 775 which serves as a partition are formed to have a tapered shape to cover end portions of the first electrode layers 771a to 771c. The partition (insulating layer) 775 is formed over the first electrode layers 771a to 771c provided in contact with the substrate 779, and an electroluminescent layer 772, a second electrode layer 773b, and a substrate 778 are provided thereover. In FIG. 8C, a rectangular solid body 777 is provided over the second electrode layer 773b in an upper part of the light emitting element, thus light extraction efficiency is improved. Needless to say, the body 777 may have another shape.

A sealing substrate is secured with a sealing member in the passive matrix light emitting device in FIGS. 8A to 8C, as well as the active matrix light emitting device in FIGS. 7A and 7B.

In this embodiment mode, with at least one body selectively provided over the second electrode, the extraction efficiency of light through the second electrode is improved. When the light extraction efficiency is improved, power consumption of a display device can be reduced. In addition, a structure which is appropriate for manufacturing such a display device can be easily formed.

### Embodiment Mode 4

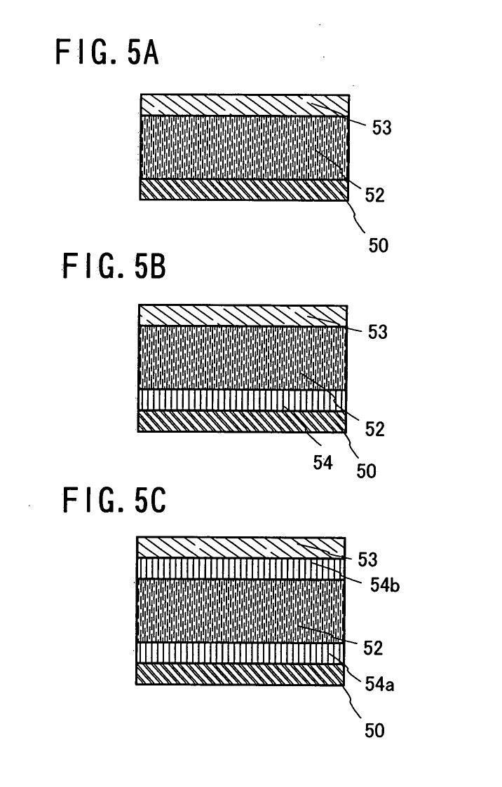

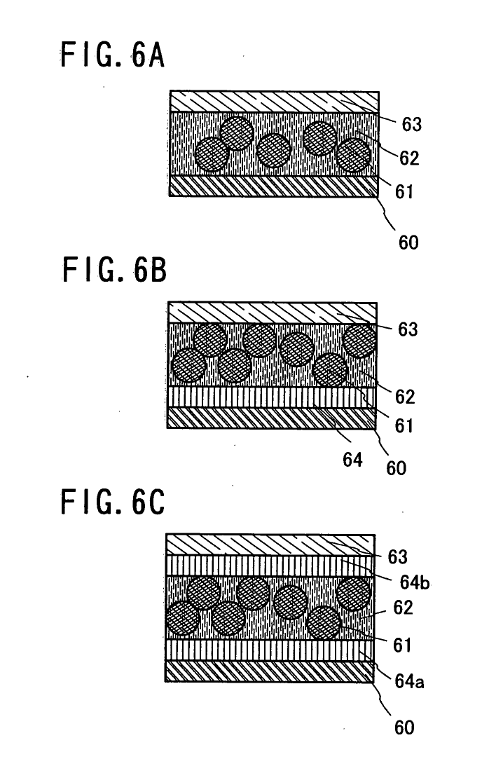

In this embodiment mode, a structure which can be applied to a light emitting element of the present invention is described with reference to FIGS. 5A to 6C.

Light emitting elements which utilize electroluminescence are classified according to whether their light emitting material is an organic compound or an inorganic compound. In general, light emitting elements having light emitting material which is an organic compound are referred to as organic EL elements, while light emitting elements having light emitting material which is an inorganic compound are referred to as inorganic EL elements.

An inorganic EL element is classified as either a dispersion type inorganic EL element or a thin-film type inorganic EL element, depending on its structure. Although these differ in that the former has an electroluminescent layer in which particles of a light emitting material are dispersed in a binder, whereas the latter has an electroluminescent layer formed of a thin film of a light emitting material, both need electrons accelerated by a high electric field. Mechanisms for obtaining light emission include donor-acceptor recombination light emission, which utilizes a donor level and an acceptor level, and localized light emission, which utilizes inner-shell electron transition of a metal ion. In general, donor-acceptor recombination light emission is employed in dispersion type inorganic EL elements and localized light emission is employed in thin-film type inorganic EL elements in many cases.

A light emitting material that can be used in the present invention includes a base material and an impurity element that serves as a light emission center. Light emission of various colors can be obtained by changing the impurity element which is included. The light emitting material can be manufactured using various methods, such as a solid phase method or a liquid phase method (e.g., a coprecipitation method). Further, a liquid phase method, such as a spray pyrolysis method, a double decomposition method, a method which employs a pyrolytic reaction of a precursor, a reverse micelle method, a method in which one or more of the above methods are combined with high-temperature baking, a freeze-drying method, or the like can be used.

A solid phase method is a method in which a base material and an impurity element or a compound containing the impurity element are weighed, mixed in a mortar, and reacted by being heated and baked in an electric furnace, so that the impurity element is included in the base material. The baking temperature is preferably 700 to 1500° C. This is because a solid-phase reaction does not proceed when the temperature is too low, and the base material decomposes when the temperature is too high. The materials may be baked in powdered form; however, it is preferable to bake the materials in pellet form. Although a comparatively high temperature compared with another method such as a liquid phase method is needed, a solid phase method is a simple method; therefore, the solid phase method has high productivity and is suitable for mass production.

A liquid phase method (e.g., a coprecipitation method) is a method in which a base material or a compound containing the base material, and an impurity element or a compound containing the impurity element are reacted in a solution, dried, and then baked. Particles of the light emitting material are distributed uniformly, and the synthesis reaction can proceed even when the particles are small and a baking temperature is lower than that in a solid phase method.

As the base material to be used for the light emitting material, a sulfide material, an oxide material, or a nitride material can be used. As a sulfide material, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used, for example. As an oxide material, zinc oxide (ZnO), yttrium oxide (Y₂O₃), or the like can be used, for example. As a nitride material, aluminum nitride (AlN), gallium nitride (GaN), indium nitride (InN), or the like can be used, for example. Alternatively, zinc selenide (ZnSe), zinc telluride (ZnTe), or the like, or a ternary mixed crystal such as calcium gallium sulfide (CaGa₂S₄), strontium gallium sulfide (SrGa₂S₄), or barium gallium sulfide (BaGa₂S₄) may be used.

As a light emission center for localized light emission, manganese (Mn), copper (Cu), samarium (Sm), terbium (Th), erbium (Er), thulium (Tm), europium (Eu), cerium (Ce), praseodymium (Pr), or the like can be used. For charge compensation, a halogen element such as fluorine (F) or chlorine (Cl) may be added.

On the other hand, as a light emission center for donor-acceptor recombination light emission, a light emitting material containing a first impurity element for forming a donor level and a second impurity element forming an acceptor level can be used. As the first impurity element, fluorine (F), chlorine (Cl), aluminum (Al), or the like can be used, for example. As the second impurity element, copper (Cu), silver (Ag), or the like can be used, for example.

In a case where the light emitting material for donor-acceptor recombination light emission is synthesized using a solid phase method, a base material, the first impurity element or a compound containing the first impurity element, and the second impurity element or a compound containing the second impurity element are weighed, mixed in a mortar, heated and baked in an electric-furnace. As the base material, the foregoing base materials can be used. As the first impurity element and the compound containing the first impurity element, fluorine (F), chlorine (Cl), aluminum sulfide (Al₂S₃) or the like can be used, for example. As the second impurity element and the compound containing the second impurity element, copper (Cu), silver (Ag), copper sulfide (Cu₂S), silver sulfide (Ag₂S), or the like can be used, for example. The baking temperature is preferably 700 to 1500° C. This is because a solid-phase reaction does not proceed when the temperature is too low, and the base material decomposes when the temperature is too high. Baking may be conducted with the materials in powdered form; however, it is preferable to conduct baking with the materials in pellet form.

As the impurity element for a solid phase reaction, a compound containing the first impurity element and the second impurity element may also be used. In that case, the impurity elements are easily diffused and the solid phase reaction proceeds readily. Therefore, a uniform light emitting material can be obtained. In addition, a high purity light emitting material can be obtained, since an unnecessary impurity element is not included therein. As the compound containing the first impurity element and the second impurity element, for example, copper chloride (CuCl), silver chloride (AgCl), or the like can be used.

Note that the concentration of these impurity elements may be 0.01 to 10 atomic %, and is preferably 0.05 to 5 atomic %, with respect to the base material.

In a case of a thin-film type inorganic EL element, an electroluminescent layer is a layer containing the foregoing light emitting material, and can be formed using a vacuum evaporation method such as a resistive heating evaporation method or an electron beam evaporation (EB evaporation) method, a physical vapor deposition (PVD) method such as a sputtering method, a chemical vapor deposition (CVD) method such as a metal organic CVD method or a low-pressure hydride transport CVD method, an atomic layer epitaxy (ALE) method, or the like.

Each of FIGS. 5A to 5C shows an example of a thin-film type inorganic EL element which can be used as the light emitting element. In FIGS. 5A to 5C, the light emitting element includes a first electrode layer 50, an electroluminescent layer 52, and a second electrode layer 53.

Each of FIGS. 5B and 5C shows a structure in which an insulating layer is provided between the electrode layer and the electroluminescent layer in the light emitting element shown in FIG. 5A. The light emitting element shown in FIG. 5B includes an insulating layer 54 between the first electrode layer 50 and the electroluminescent layer 52. The light emitting element shown in FIG 5C includes an insulating layer 54a between the first electrode layer 50 and the electroluminescent layer 52, and an insulating layer 54b between the second electrode layer 53 and the electroluminescent layer 52. Thus, the insulating layer may be provided between the electroluminescent layer and one of the electrode layers interposing the electroluminescent layer, or may be provided between the electroluminescent layer and each of the electrode layers interposing the electroluminescent layer. In addition, the insulating layer may be a single layer or a stacked layer including a plurality of layers.

Note that the insulating layer 54 is provided in contact with the first electrode layer 50 in FIG. 5B; alternatively, the insulating layer 54 may be provided in contact with the second electrode layer 53 by reversing the positions of the insulating layer and the electroluminescent layer.

In a case of a dispersion type inorganic EL element, a film-shaped electroluminescent layer is formed by dispersing particles of light emitting material in a binder. In a case in which particles with desired size cannot be sufficiently obtained by a method of manufacturing the light emitting material, the light emitting material may be processed into particles by being crushed in a mortar or the like. The binder is a substance for fixing dispersed particles of light emitting material in place and maintaining the shape of an electroluminescent layer. The light emitting material is dispersed uniformly through the electroluminescent layer and fixed in place by the binder.

In a case of a dispersion type inorganic EL element, a method for forming the electroluminescent layer can be a droplet discharging method by which the electroluminescent layer can be selectively formed, a printing method (screen printing, offset printing, or the like), a coating method such as a spin coat method or the like, a dipping method, a dispenser method, or the like. There is no particular limitation on a film thickness, but preferably it is in a range of 10 to 1000 nm. In addition, in the electroluminescent layer containing the light emitting material and the binder, the weight percent of the light emitting material is preferably greater than or equal to 50 wt % and less than or equal to 80 wt %.

Each of FIGS. 6A to 6C shows an example of a dispersion type inorganic EL element which can be used as the light emitting element. A light emitting element shown in FIG. 6A has a stacked layer structure including a first electrode layer 60, an electroluminescent layer 62, and a second electrode layer 63. The electroluminescent layer 62 contains a light emitting material 61 fixed by a binder.

As a binder that can be used in this embodiment mode, an organic material or an inorganic material can be used. Alternatively, a mixed material containing an organic material and an inorganic material may be used. As the organic material, a polymer having comparatively high dielectric constant such as a cyanoethyl cellulose based resin or the like, or a resin such as polyethylene, polypropylene, a polystyrene based resin, a silicone resin, an epoxy resin, vinylidene fluoride, or the like can be used. Alternatively, a heat resistant high molecular weight material such as aromatic polyamide or polybenzimidazole, or a siloxane resin may be used. Note that a siloxane resin is a resin including a Si—O—Si bond. Siloxane has a skeleton structure having a bond between silicon (Si) and oxygen (O), and as a substituent, an organic group having at least hydrogen (such as an alkyl group or an aromatic hydrocarbon) is used. As the substituent, a fluoro group may be used. Alternatively, an organic group containing at least hydrogen, and a fluoro group may be used as the substituent. Further, a resin material such as a vinyl resin such as polyvinyl alcohol or polyvinylbutyral, a phenol resin, a novolac resin, an acrylic resin, a melamine resin, a urethane resin, an oxazole resin (e.g., polybenzoxazole), may be used. Fine particles having a high dielectric constant, such as particles of barium titanate (BaTiO₃) or strontium titanate (SrTiO₃) can also be mixed with these resins appropriately to adjust the dielectric constant.

The inorganic material contained in the binder can be formed using a material selected from silicon oxide (SiOₓ), silicon nitride (SiNₓ), silicon containing oxygen and nitrogen, aluminum nitride (AlN), aluminum or aluminum oxide (Al₂O₃) containing oxygen and nitrogen, titanium oxide (TiO₂), BaTiO₃, SrTiO₃, lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), zirconium oxide (ZrO₂), ZnS, or another substance containing an inorganic material. When an inorganic material having a high dielectric constant is contained in the organic material (by addition or the like), the dielectric constant of the electroluminescent layer including the light emitting material and the binder can be more effectively controlled and can be made even higher.

In a manufacturing process, the light emitting materials are dispersed in a solution containing the binder. As a solvent for the solution containing the binder which can be used in this embodiment mode, a solvent in which a binder material can be dissolved and which can form a solution having a viscosity suitable for a method for forming the electroluminescent layer (various wet processes) with a desired thickness may be appropriately selected. An organic solvent or the like can be used. In a case of using a siloxane resin as the binder, for example, propylene glycol monomethyl ether, propylene glycol monomethyl ether acetate (also referred to as PGMEA), 3-methoxy-3-methyl-1-butanol (also referred to as MMB), or the like can be used.

Each of FIGS. 6B and 6C shows a structure in which an insulating layer is provided between the electrode layer and the electroluminescent layer in the light emitting element shown in FIG. 6A. The light emitting element shown in FIG. 6B includes an insulating layer 64 between the first electrode layer 60 and the electroluminescent layer 62. The light emitting element shown in FIG. 6C includes an insulating layer 64a between the first electrode layer 60 and the electroluminescent layer 62, and an insulating layer 64b between the second electrode layer 63 and the electroluminescent layer 62. Thus, the insulating layers may be provided between the electroluminescent layer and one of the electrode layers interposing the electroluminescent layer, or may be provided between the electroluminescent layer and each of the electrode layers interposing the electroluminescent layer. In addition, the insulating layer may be a single layer or a stacked layer including a plurality of layers.

Note that the insulating layer 64 is provided in contact with the first electrode layer 60 in FIG. 6B; alternatively, the insulating layer 64 may be provided in contact with the second electrode layer 63 by reversing the positions of the insulating layer and the electroluminescent layer.

There is no particular limitation on the insulating layer 54 in FIGS. 5A to 5C and the insulating layer 64 in FIGS. 6A to 6C, but they preferably have high withstand voltage and are dense films. Further, the insulating layers preferably have high dielectric constant. For example, silicon oxide (SiO₂), yttrium oxide (y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like can be used. Alternatively, a mixed film of those materials or a stacked layer film including two or more of those materials can be used. An insulating film of a material selected from the foregoing materials can be formed by sputtering, vapor deposition, CVD, or the like. Alternatively, the insulating layer may be formed by dispersing particles of a material selected from the foregoing insulating materials in a binder. A material for the binder may be the same as the binder contained in the electroluminescent layer and may be formed by the same method. There is no particular limitation on a film thickness, but preferably it is in a range of 10 to 1000 nm.

The light emitting element of this embodiment emits light when voltage is applied between the pair of electrode layers interposing the electroluminescent layer. The light emitting element of this embodiment can operate with either direct current driving or alternate current driving.

When at least one body is selectively provided over the second electrode, the extraction efficiency of light through the second electrode is improved in a light emitting element in this embodiment mode. When the light extraction efficiency is improved, power consumption of a display device can be reduced. In addition, a structure which is appropriate for manufacturing such a display device can be easily formed.

### Embodiment Mode 5

A light emitting device of the present invention can be used as a display portion of an electronic appliance. An electronic appliance shown in this embodiment mode includes a light emitting element and a light emitting device described in Embodiment Modes 1 to 4. Therefore, an electronic appliance with lower power consumption can be provided.

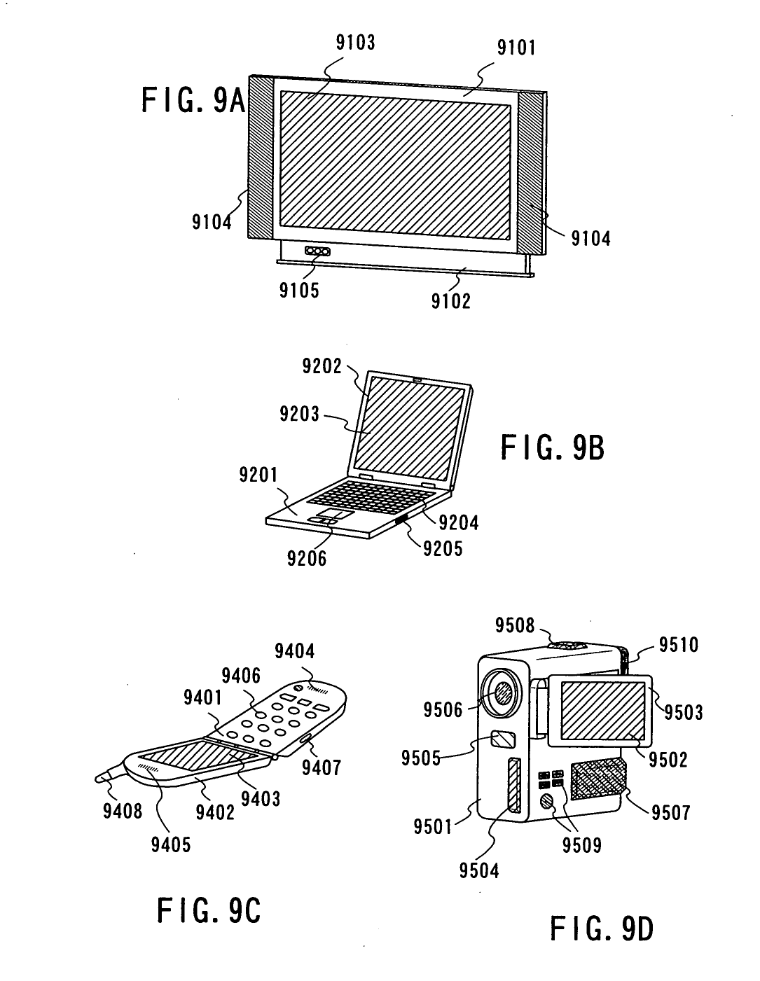

As electronic appliances manufactured utilizing the present invention, cameras such as a video camera and a digital camera, a goggle type display, a navigation system, an audio reproducing device (car audio, audio components, or the like), a computer, a game machine, a portable information terminal (a mobile computer, a mobile phone, a portable game machine, an electronic book reader, or the like), an image reproducing device provided with a recording medium (specifically, a device which reproduces the content of a recording medium such as a digital versatile disc (DVD) and which is provided with a display device for displaying a reproduced image), and the like can be given. Specific examples of these electronic appliances are shown in FIGS. 9A to 9D.

FIG. 9A shows a television apparatus utilizing the present invention. The television apparatus includes a chassis 9101, a supporting board 9102, a display portion 9103, a speaker portion 9104, a video input terminal 9105, and the like. In the television apparatus, the display portion 9103 has light emitting elements arranged in matrix, which are similar to those described in Embodiment Modes 1 to 4. Since light extraction efficiency of the light emitting elements is improved, the power consumption of the television apparatus can be reduced. Thus, the television apparatus can be made suitable for living environments.

FIG. 9B shows a computer utilizing the present invention. The computer includes a main body 9201, a chassis 9202, a display portion 9203, a keyboard 9204, an external connection port 9205, a pointing device 9206, and the like. In the computer, the display portion 9203 has light emitting elements arranged in matrix, which are similar to those described in Embodiment Modes 1 to 4. Since light extraction efficiency of the light emitting elements is improved, the power consumption of the computer can be reduced.

FIG. 9C shows a mobile phone including a main body 9401, a chassis 9402, a display portion 9403, an audio input portion 9404, an audio output portion 9405, an operation key 9406, an external connection port 9407, an antenna 9408, and the like. In the mobile phone, the display portion 9403 has light emitting elements arranged in matrix, which are similar to those described in Embodiment Modes 1 to 4. Since light extraction efficiency of the light emitting elements is improved, the power consumption of the mobile phone can be reduced and the convenience can be enhanced.

FIG. 9D shows a camera including a main body 9501, a display portion 9502, a chassis 9503, an external connection port 9504, a remote control receiving portion 9505, an image receiving portion 9506, a battery 9507, an audio input portion 9508, an operation key 9509, an eye piece portion 9510, and the like. In this camera, the display portion 9502 has light emitting elements arranged in matrix, which are similar to those described in Embodiment Modes 1 to 4. Since light extraction efficiency of the light emitting elements is improved, the power consumption of the camera can be reduced and the convenience can be enhanced.

As described above, the application range of the present invention is extremely wide and a light emitting device of the present invention can be used for electronic appliances in various fields. By utilizing the present invention, an electronic appliance with low power consumption can be manufactured.

### Embodiment Mode 6

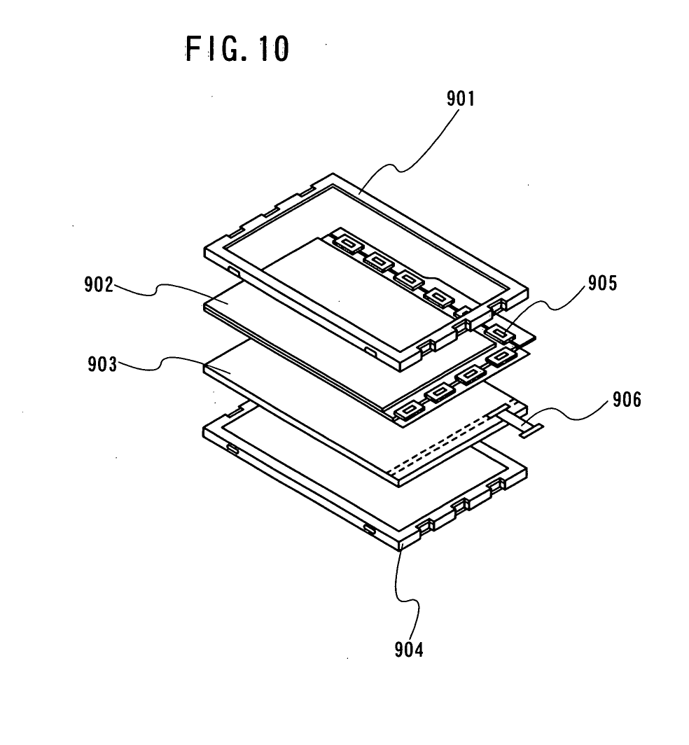

A light emitting device of the present invention can be used as a lighting device. A mode of using a light emitting element to which the present invention is applied as a lighting device is described with reference to FIG. 10.

FIG. 10 shows an example of a liquid crystal display device using a light emitting device to which the present invention is applied as a backlight. The liquid crystal display device shown in FIG. 10 includes a chassis 901, a liquid crystal layer 902, a backlight 903, and a chassis 904. The liquid crystal layer 902 is connected to a driver IC 905. In addition, a light emitting device of the present invention is used for the backlight 903 and current is supplied thereto through a terminal 906.

By using a light emitting device to which the present invention is applied as a backlight of a liquid crystal display device, a bright backlight with lower power consumption can be obtained. In addition, a light emitting device to which the present invention is applied is a lighting device which performs surface light emission, and the area thereof can be enlarged; therefore, the area of the backlight can be increased and the screen of a liquid crystal display device can be also enlarged. Further, since the light emitting device is thin and consumes less power compared with another light emitting device, reduction in thickness and power consumption in the display device can be achieved.

Needless to say, a light emitting device of the invention can also be used as a planar lighting device other than a backlight of a liquid crystal display device.

This application is based on Japanese Patent Application serial No. 2006-154081 filed in Japan Patent Office on Jun. 1, 2006, the entire contents of Which are hereby incorporated by reference.

What is claimed is:

1. A manufacturing method of a light emitting device, comprising:
forming a first electrode over a substrate;
forming a light emitting layer containing an inorganic compound over the first electrode;
forming a light transmitting second electrode over the light emitting layer;
forming a light transmitting film over the light transmitting second electrode;
forming a mask layer over the light transmitting film; and
forming a body selectively on a surface of the light transmitting second electrode by etching the light transmitting film using the mask layer,
wherein light emitted from the light emitting layer transmits the light transmitting second electrode and the body.

2. A manufacturing method of a light emitting device, according to claim 1, wherein the etching is wet etching.

3. A manufacturing method of a light emitting device, according to claim 1, wherein the light transmitting film is formed by a sputtering method or a vapor deposition method.

4. A manufacturing method of a light emitting device, according to claim 1, wherein a plurality of the bodies are formed and the bodies are formed into columnar shapes:

5. A manufacturing method of a light emitting device, according to claim 1, wherein the first electrode reflects the light emitted from the light emitting layer.

6. A manufacturing method of a light emitting device, according to claim 1, wherein the first electrode transmits the light emitted from the light emitting layer.

7. A manufacturing method of a light emitting device, according to claim 1, wherein the light emitting device is incorporated into one selected from the group consisting of a television apparatus, a computer, a mobile phone, a camera, and a backlight of a liquid crystal display device.

8. A manufacturing method of a light emitting device, comprising:
forming a first electrode over a substrate;
forming a light emitting layer containing an inorganic compound over the first electrode;
forming a light transmitting second electrode over the light emitting layer;
forming a protective layer over the light transmitting second electrode;
forming a light transmitting film over the protective layer;
forming a mask layer over the light transmitting film; and
forming a body selectively on a surface of the light transmitting second electrode with the protective layer interposed between the body and the surface by etching the light transmitting film using the mask layer,
wherein light emitted from the light emitting layer transmits the light transmitting second electrode and the body.

9. A manufacturing method of a light emitting device, according to claim 8, wherein the etching is wet etching.

10. A manufacturing method of a light emitting device, according to claim 8, wherein the light transmitting film is formed by a sputtering method or a vapor deposition method.

11. A manufacturing method of a light emitting device, according to claim 8, wherein a plurality of the bodies are formed and the bodies are formed into columnar shapes.

12. A manufacturing method of a light emitting device, according to claim 8, wherein the first electrode reflects the light emitted from the light emitting layer.

13. A manufacturing method of a light emitting device, according to claim 8, wherein the first electrode transmits the light emitted from the light emitting layer.

14. A manufacturing method of a light emitting device, according to claim 8, wherein the light emitting device is incorporated into one selected from the group consisting of a television apparatus, a computer, a mobile phone, a camera, and a backlight of a liquid crystal display device.

15. A manufacturing method of a light emitting device, comprising:
forming a first electrode over a substrate;
forming a light emitting layer containing an inorganic compound over the first electrode;
forming a light transmitting second electrode over the light emitting layer;
forming a photosensitive and light transmitting film over the light transmitting second electrode; and
forming a body selectively on a surface of the light transmitting second electrode by light exposure and development of the photosensitive and light transmitting film,
wherein light emitted from the light emitting layer transmits the light transmitting second electrode and the body.

16. A manufacturing method of a light emitting device, according to claim 15, wherein the light transmitting film is formed by a sputtering method or a vapor deposition method.

17. A manufacturing method of a light emitting device, according to claim 15, wherein a plurality of the bodies are formed and the bodies are formed into columnar shapes.

18. A manufacturing method of a light emitting device, according to claim 15, wherein the first electrode reflects the light emitted from the light emitting layer.

19. A manufacturing method of a light emitting device, according to claim 15, wherein the first electrode transmits the light emitted from the light emitting layer.

20. A manufacturing method of a light emitting device, according to claim 15, wherein the light emitting device is incorporated into one selected from the group consisting of a television apparatus, a computer, a mobile phone, a camera, and a backlight of a liquid crystal display device.

21. A manufacturing method of a light emitting device, comprising:
forming a first electrode over a substrate;
forming a light emitting layer containing an inorganic compound over the first electrode;
forming a light transmitting second electrode over the light emitting layer;
forming a protective layer over the light transmitting second electrode;
forming a photosensitive and light transmitting film over the protective layer; and
forming a body selectively on a surface of the light transmitting second electrode with the protective layer interposed between the body and the surface by light exposure and development of the photosensitive and light transmitting film,
wherein light emitted from the light emitting layer transmits the light transmitting second electrode and the body.

22. A manufacturing method of a light emitting device, according to claim 21, wherein the light transmitting film is formed by a sputtering method or a vapor deposition method.

23. A manufacturing method of a light emitting device, according to claim 21, wherein a plurality of the bodies are formed and the bodies are formed into columnar shapes.

24. A manufacturing method of a light emitting device, according to claim 21, wherein the first electrode reflects the light emitted from the light emitting layer.

25. A manufacturing method of a light emitting device, according to claim 21, wherein the first electrode transmits the light emitted from the light emitting layer.

26. A manufacturing method of a light emitting device, according to claim 21, wherein the light emitting device is incorporated into one selected from the group consisting of a television apparatus, a computer, a mobile phone, a camera, and a backlight of a liquid crystal display device.
